(19) United States
(12) Patent Application Publication
(10) Pub. No.: US 2002/0063314 A1
(43) Pub. Date: May 30, 2002

(54) Tapeless micro-leadframe

(76) Inventors: Mathew S. Read, Irvine, CA (US); Robbie U. Villanueva, Rancho Santa Margarita, CA (US)

Correspondence Address: ANATOLY WEISER, BROBECK, PHLEGER & HARRISON LLP, 12390 EL CAMINO REAL, SAN DIEGO, CA, 92130, US

(21) Appl. No.: 09/727,425

(22) Filed: Nov. 30, 2000

(51) Int. Cl. H01L 23/495; H01L 21/44

(52) U.S. Cl. 257/666; 438/123

(57) ABSTRACT

A tapeless micro-leadframe has a plurality of preload extension tabs protruding from a flat base for integrated circuit packaging, to reduce the possibility of undesirable leakage or bleeding of mold flash.

### BACKGROUND OF THE INVENTION

1. Field of the Invention

The present invention relates to integrated circuit packaging, and more particularly, to micro-leadframe packaging.

2. Background Art

Micro-leadframes have been used in the semiconductor integrated circuit industry as miniaturized replacements for printed circuit boards to reduce the size and cost of integrated circuit packages. Conventional micro-leadframe packages have been implemented for circuit connections with low pin count semiconductor devices in various applications in which small-size circuit packages are required. For example, conventional micro-leadframe packages have been implemented in mobile telephones and other hand-held devices.

A conventional micro-leadframe is made of a flat base with planar conductive lead patterns to provide electrically conductive paths for integrated circuits. A conventional semiconductor integrated circuit package typically includes a semiconductor die which contains an integrated circuit enclosed within a plastic mold cap. In a typical integrated circuit package, a die using gold wire bonds from die pads to leadframe leads are used to make electrical connections with the external conductive lead pattern of the micro-leadframe.

In a conventional fabrication process, the plastic mold cap of the integrated circuit package is heated and injected between a mold cavity and the micro-leadframe. In order to prevent any mold flash from reaching the exposed pads and die paddle, a tape is applied to the bottom of the conventional micro-leadframe according to the current industry standard. The need for application of tapes in a conventional fabrication process usually results in increased raw materials cost and causes clamping problems during wire bonding and subsequent removal of the tapes.

Therefore, there is a need for an improved micro-leadframe package without the use of tapes to prevent undesirable leakage of mold flash. Furthermore, there is a need for a method of fabricating an improved micro-leadframe package while obviating the need for applying a tape to the micro-leadframe.

### SUMMARY OF THE INVENTION

The present invention provides a micro-leadframe for mounting an integrated circuit, generally comprising a flat base having a conductive lead pattern to provide electrically conductive paths for the integrated circuit, and a plurality of preload extension tabs arranged about the conductive lead pattern. The preload extension tabs protrude at an angle to a predetermined height above the flat base.

Furthermore, the present invention provides a method of packaging an integrated circuit. The method generally includes the step of providing a patterned flat base with a plurality of preload extension tabs protruding from the flat base at an angle with respect to the flat base to a predetermined height above the flat base.

Advantageously, the micro-leadframe and the method for packaging an integrated circuit in an embodiment according to the present invention allows the packaging process to be simplified by obviating the need for applying a tape to the micro-leadframe, thereby avoiding the problems associated with the application of tapes to conventional micro-leadframes.

Further features and advantages of the invention as well as the structure and operation of various embodiments of the invention are described in detail below with reference to the accompanying drawings.

### BRIEF DESCRIPTION OF THE DRAWINGS

The present invention will be described with particular embodiments thereof, and references will be made to the drawings in which:

FIG. 1 shows a sectional view of a micro-leadframe with a plurality of preload retention tabs in an embodiment according to the present invention;

FIG. 2 shows a sectional view of a top mold platten used in a process for attaching the mold compound or encapsulation material of a semiconductor device to the micro-leadframe in an embodiment according to the present invention;

FIG. 3 shows a sectional view illustrating the clamping of a micro-leadframe with heated top and bottom mold plattens in an embodiment according to the present invention;

FIG. 4 shows a sectional view of an integrated circuit with the preload extension tabs in an embodiment according to the present invention;

FIG. 5 shows a simplified top plan view of the integrated circuit of FIG. 4, with the preload extension tabs in an embodiment according to the present invention; and

FIG. 6 shows a bottom plan view of an example of a conductive lead pattern of the micro-leadframe in an embodiment according to the present invention.

### DETAILED DESCRIPTION

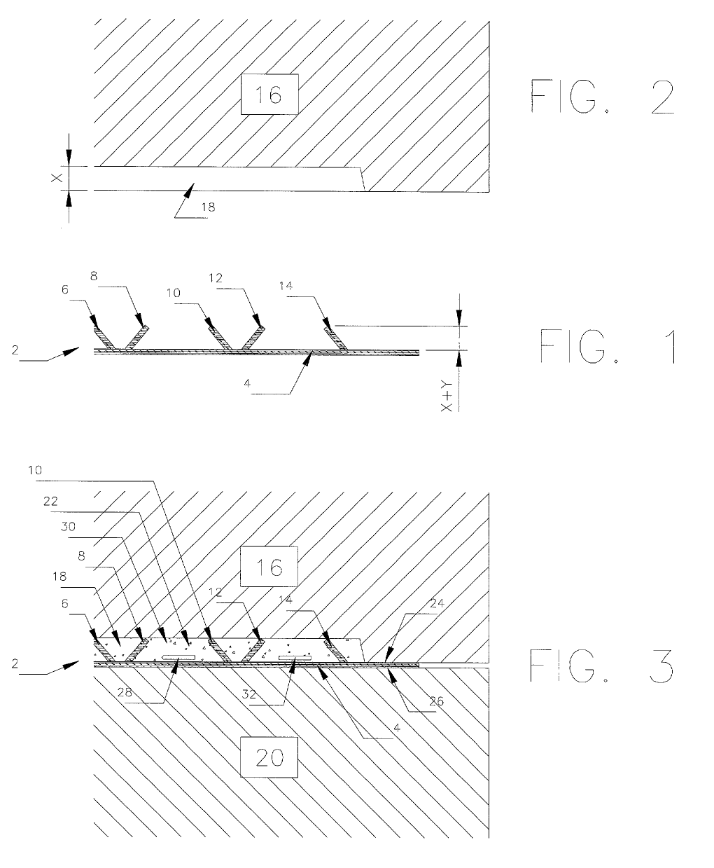

FIG. 1 shows a sectional view of a micro-leadframe 2 which comprises a flat base for and a plurality of preload extension tabs 6, 8, 10, 12 and 14 protruding from the flat base 4 in an embodiment according to the present invention. The flat base 4 has a plurality of conductive lead patterns, which are not shown in the sectional view of FIG. 1, to provide electrically conductive paths for integrated circuits to be attached to the micro-leadframe. The preload extension tabs 6, 8, 10, 12 and 14 and the flat base 4 are formed in one integral piece. In an embodiment, the preload extension tabs are formed as part of the flat base and bent upward protruding at a predefined angle with respect to the flat base. The conductive lead patterns for integrated circuit packages can be designed, patterned and etched on the flat base 4 in a conventional manner similar to that which is used for a conventional planar micro-leadframe known to a person skilled in the art.

FIG. 2 shows a sectional view of a conventional top mold platten 16 which is used for heating and molding the plastic resin mold compound or encapsulant of an integrated circuit package against the micro-leadframe 2 of FIG. 1 to produce an integrated micro-leadframe package. The top mold platten 16 typically comprises a large, flat chunk of steel with heater rods (not shown in FIG. 2) to heat the plastic resin mold compound of the integrated circuit package to a desired temperature. As shown in FIG. 2, the top mold platten 16 has an indentation which defines a mold cavity 18 having a predetermined depth x equal to the height of the integrated circuit package (not shown in FIG. 2), which is heated to allow the heated mold compound to be attached to the micro-leadframe of FIG. 1 in a process that will be described in further detail below with reference to FIG. 3.

As shown in FIG. 1, the preload extension tabs 6, 8, 10, 12 and 14 extend from the flat base 4 at an angle with respect to the flat base to a predetermined height x+y above the flat base. The height x+y of the preload extension tabs 6, 8, 10, 12 and 14 is slightly greater than the depth x of the mold cavity 18 in the top mold platten 16 of FIG. 2 for secure attachment of the bottom of the micro-leadframe to top of the bottom mold platten in an embodiment according to the present invention.

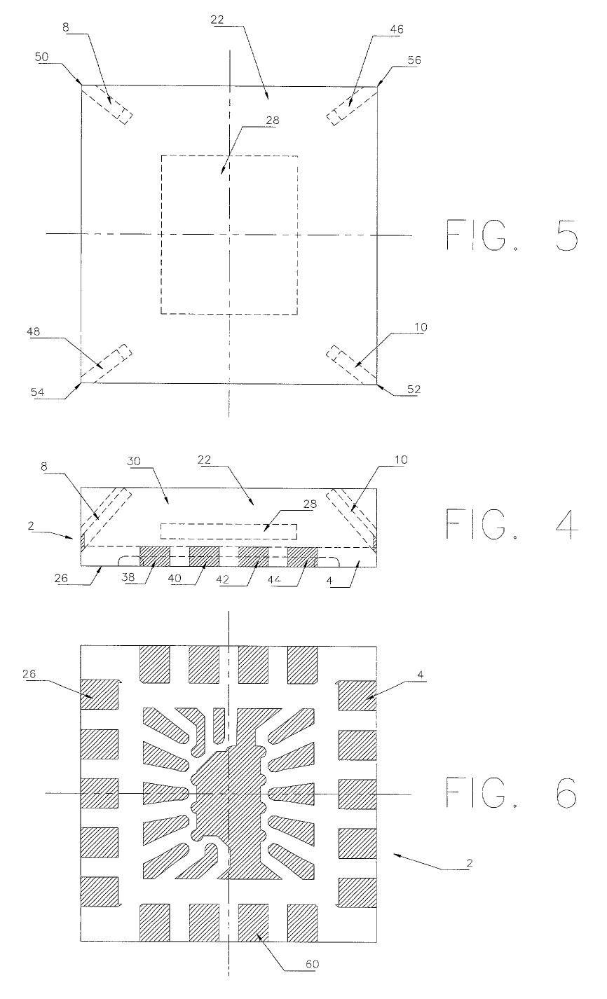

FIG. 3 shows a sectional view of an integrated circuit on a micro-leadframe being overmolded by heated top and bottom mold plattens during the manufacturing process in an embodiment according to the present invention. In FIG. 3, a heated top mold platten 16 forces the micro-leadframe extension tabs 6, 8, 10, 12 and 14 against the top cavity surface 34 of the top mold platten 16, while a heated bottom mold platten 20 exerts a pressure on the bottom surface 26 of the flat base 4. The bottom mold platten 20 typically comprises a large, flat chunk of steel with heater rods (not shown in FIG. 3) similar to the top mold platten 16 but without the indentation to provide the mold cavity for the semiconductor integrated circuit package. The integrated circuit 22 comprises a semiconductor die 28 enclosed in a plastic mold cap 30. An example of a typical integrated circuit package with flipchip bonding will be described in further detail below with reference to FIG. 4.

In the embodiment shown in FIG. 3, the integrated circuit package 22 includes a plurality of semiconductor dies 28 and 32 which are enclosed within the mold cap 30. The mold cap 30, which comprises a plastic resin material in an embodiment, is heated by the top and bottom mold plattens 16 and 20 and attached to the micro-leadframe 2 under heated pressure. The preload extension tabs 6, 8, 10, 12 and 14 comprise bent flexible metal segments protruding from the top surface 24 of the flat base 4 of the micro-leadframe 2 in an embodiment. During the molding process, the preload extension tabs 6, 8, 10, 12 and 14 make contact with the top 34 of the mold cavity 18 when the heated top mold platten 16 presses the micro-leadframe 2 against the top of the bottom mold platten 20.

FIG. 4 shows a more detailed sectional view of an integrated circuit 22 with a conventional flipchip configuration. In FIG. 4, the integrated circuit 22 comprises a plastic resin mold cap 30 and a semiconductor die 28 within the mold cap 30. A plurality of lead fingers 38, 40, 42 and 44 are connected between the micro-leadframe 2 and the die 28 to provide electrical connections. The lead fingers 38, 40, 42 and 44 also support the semiconductor die 28.

FIG. 5 shows a top plan view of the integrated circuit package of FIG. 4 in an embodiment in which four preload extension tabs 8, 10, 46 and 48 are provided to secure four corners 50, 52, 54 and 56 of the integrated circuit package 22, which has a square top area in this example. In an embodiment, the sectional view of FIG. 4 is obtained along the sectional line A-A′ in FIG. 5. In an alternate embodiment, the preload extension tabs may be implemented at locations along the edges of the integrated circuit package with a square or rectangular top area. Other arrangements of preload extension tabs may also be implemented in various embodiments within the scope of the present invention.

FIG. 6 shows the bottom plan view of a typical example of a conductive lead pattern 60 on the bottom surface 26 of the flat base 4 of the micro-leadframe 2. Various conductive lead patterns can be designed and etched on the flat base 4 of the micro-leadframe 2 in a conventional manner known to a person skilled in the art. When a semiconductor integrated circuit with a typical flipchip configuration such as the one shown in FIG. 4 is attached to the micro-leadframe 2 in an embodiment according to the present invention, the lead fingers which are formed as part of the conductive lead pattern on the micro-leadframe provide electrical connections to the flipchip die.

From the above description of the invention it is manifest that various equivalents can be used to implement the concepts of the present invention without departing from its scope. Moreover, while the invention has been described with specific reference to certain embodiments, a person of ordinary skills in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many equivalents, rearrangements, modifications, and substitutions without departing from the scope of the invention.

What is claimed is:

1. A micro-leadframe for mounting at least one integrated circuit, comprising:
a flat base having at least one conductive lead pattern to provide electrically conductive paths for said at least one integrated circuit; and
a plurality of preload extension tabs arranged about said at least one conductive lead pattern, the preload extension tabs protruding at an angle with respect to the flat base to a predetermined height above the flat base.

2. The micro-leadframe of claim 1, wherein said at least one integrated circuit is positioned on said at least one conductive lead pattern of the flat base, said at least one integrated circuit comprising a mold cap having a predetermined height above the flat base.

3. The micro-leadframe of claim 2, wherein said at least one integrated circuit package further comprises a semiconductor die within the mold cap.

4. The micro-leadframe of claim 3, wherein the semiconductor die comprises a flipchip die.

5. The micro-leadframe of claim 3, wherein the preload extension tabs are directly connected to the mold cap.

6. A micro-leadframe package, comprising:
a flat base having a conductive lead pattern;
an integrated circuit connected to the conductive lead pattern of the flat base;
a plurality of preload extension tabs arranged about the conductive lead pattern, the preload extension tabs protruding at an angle with respect to the flat base into the integrated circuit package to a predetermined height above the flat base.

7. The micro-leadframe package of claim 6, wherein the integrated circuit comprises a plastic mold cap having a predetermined height above the flat base.

8. The micro-leadframe package of claim 7, wherein the integrated circuit further comprises a semiconductor die within the mold cap.

9. The micro-leadframe package of claim 8, wherein said at least one integrated circuit package further comprises a plurality of flipchip connections between the semiconductor die and the conductive lead pattern.

10. The micro-leadframe package of claim 8, wherein the preload extension tabs are directly connected to the flat base.

11. A method of packaging an integrated circuit, comprising the steps of:
providing a patterned micro-leadframe having a flat base;
forming a plurality of preload extension tabs protruding from the flat base at a predetermined angle with respect to the flat base to a predetermined height above the flat base; and
attaching a mold compound to the micro-leadframe.

12. The method of claim 11, further comprising the step of providing a top mold platten.

13. The method of claim 12, wherein the step of attaching the mold compound to the micro-leadframe comprises the step of heating the top mold platten and forcing the top mold platten against the preload extension tabs.

14. The method of claim 13, further comprising the step of providing a bottom mold platten.

15. The method of claim 14, wherein the step of attaching the mold compound to the micro-leadframe further comprises the steps of heating the bottom mold platten and pressing the bottom mold platten against the patterned flat base.

16. The method of claim 11, wherein the step of forming the preload extension tabs comprises the step of bending the preload extension tabs to the predetermined angle with respect to the flat base.
